(19) United States
(12) Patent Application Publication
(10) Pub. No.: US 2011/0263108 A1
(43) Pub. Date: Oct. 27, 2011

(54) Method of fabricating semiconductor quantum dots

(75) Inventors: Hongbo Lan, Jinan (CN); Udo W. Pohl, Berlin (DE); Dieter Bimberg, Berlin (DE)

(73) Assignee: Technische Universitat Berlin

(21) Appl. No.: 12/662,661

(22) Filed: Apr. 27, 2010

(51) Int. Cl. H01L 21/20

(52) U.S. Cl. 438/492; 438/504; 257/E21.09

(57) ABSTRACT

The invention relates to a method of fabricating at least one semiconductor quantum dot at a predefined position, comprising the steps of: patterning a semiconductor base material using nanoimprint lithography and an etching step, to form at least one nano-hole at the predefined position in the semiconductor base material; and growing the at least one semiconductor quantum dot in or on top of the at least one nano-hole by metalorganic chemical vapor deposition.

### BACKGROUND OF THE INVENTION

The invention relates to a method of fabricating semiconductor quantum dots.

Fabrication of quantum dot (QD) arrays is attractive for a wide range of applications in nanoelectronics, nanooptoelectronics and quantum devices, such as single-electron transistors, quantum dot-based lasers and LEDs, quantum dot memories, infrared photodetectors, solar cells, and others.

Self-assembly employing the Stranski-Krastnow growth mode has been considered as the most promising approach to form quantum dot arrays. The non-uniformity and random ordering resulting from the self-assembly processes, however, are detrimental to potential applications, prohibiting the type of engineering control necessary for complex systems, diminishing the potential advantages of quantum dots usage in optoelectronic devices such as low threshold current-density, narrow gain bandwidth, and increased characteristic temperature. In addition, regions with ordered quantum dots only appear in small, randomly oriented domains, and only short-range ordering of quantum dot positions with respect to next neighbours can be achieved in quantum dot arrays grown using the Stranski-Krastnow mode.

In “High optical quality InAs site-controlled quantum dots grown on soft photocurable nanoimprint lithography patterned GaAs substrates” (Applied Physics Letters Vol. 95, p. 173108 (2009)) Cheng et al. discloses a method wherein GaAs substrates are patterned to achieve InAs site-controlled quantum dots. In this work Molecular Beam Epitaxy (MBE) was employed to fabricate the quantum dots.

Xu et al., and Jung et al. both presented methods based on anodic aluminum oxide (AAO) templates to make a patterned substrate (see Xu et al.: “Process to grow a highly ordered quantum dot array, quantum dot array grown in accordance with the process, and devices incorporating same”, International Application WO 2006/017220 A1; and Jung et al.: “Fabrication of the uniform CdTe quantum dot array on GaAs substrate utilizing nanoporous alumina masks”, Current Applied Physics Vol. 6, p. 1016-1019 (2006)). The AAO approach has inherent limitations: It can only create hexagonal patterns, and it is not possible to accurately control the size and the position of the generated pattern. Therefore no large-area, highly uniform and ordered quantum dot arrays with high throughput can be achieved. Furthermore, both methods cannot form quantum dot arrays with a low density for achieving single quantum dots.

Qian et al. demonstrated the fabrication of optically active uniform InGaAs quantum dot arrays by combining nanosphere lithography and bromine ion-beam-assisted etching on a single InGaAs/GaAs quantum well (Qian et al.: “Uniform InGaAs quantum dot arrays fabricated using nanosphere lithography”, Applied Physics Letters Vol. 93, p. 231907 (2008)). This approach has a low productivity for the nanosphere lithography and can only produce hexagonal lattices. Moreover, it can not create a low-density quantum dot array.

### OBJECTIVE OF THE PRESENT INVENTION

Accordingly, the objective of the present invention is to provide a method for fabricating quantum dots.

Another objective of the present invention is to provide a method capable of forming large-area, highly uniform and ordered quantum dot arrays at predefined positions for quantum dot-based products.

### BRIEF SUMMARY OF THE INVENTION

An embodiment of the invention relates to a method of fabricating at least one semiconductor quantum dot at a predefined position, comprising the steps of: patterning a semiconductor base material using nanoimprint lithography and an etching step, to form at least one nano-hole at the predefined position in the semiconductor base material; and growing the at least one semiconductor quantum dot in or on top of the at least one nano-hole by metalorganic chemical vapor deposition. This embodiment achieves an outstanding uniformity and ordering of the quantum dots. Furthermore, this embodiment realizes an accurate site control for quantum dot arrays and single quantum dots. Furthermore, this embodiment has the ability to create patterned substrates with either high or low dense structures simultaneously.

According to a preferred embodiment, the method further comprises the steps of: growing a first semiconductor buffer layer on a substrate, said first semiconductor buffer layer forming said semiconductor base material; and patterning the first semiconductor buffer layer based on said nanoimprint lithography and said etching step, to form said nano-hole in the first semiconductor buffer layer. The first semiconductor buffer layer is not mandatory, however, it enhances the surface quality and thus supports the growth of quantum dots later on.

Preferably, the method also comprises the steps of growing a second buffer layer on the patterned first semiconductor buffer layer, and growing the semiconductor quantum dot in the nano-hole of the second semiconductor buffer layer. The second semiconductor buffer layer further enhances the surface quality and thus the quality of the quantum dots.

In order to support the growth of the second semiconductor buffer layer, surface oxide from the first semiconductor buffer layer is preferably removed before growing the second semiconductor buffer layer on the patterned first semiconductor buffer layer.

In a further preferred embodiment, photo nanoimprint lithography is applied. Accordingly, this embodiment comprises the steps of applying a photo curable liquid resist to the semiconductor base material, pressing a mold and the semiconductor base material together, curing the photo curable liquid resist, and separating the mold from the cured photo curable liquid resist. For instance, the photo curable liquid resist may be an UV-light curable liquid resist which may be cured by applying UV-light. Nanoimprint lithography (NIL) allows fabricating micro/nanometer scale patterns with low cost, high throughput and high resolution. It is considered as an enabling, cost-effective, simple pattern transfer process for various micro/nano devices and structures fabrications. The unique advantage of nanoimprint lithography compared to other patterning techniques is the ability to create 3-D and large-area micro/nano structures with low cost and high throughput particularly for soft UV-NIL. Nanoimprint lithography is based on direct mechanical deformation of a resist to replicate the pattern, no high-energy beam is involved which can avoid potential damage to the substrate. Therefore, soft UV-NIL (UV-based nanoimprint lithography using soft molds) offers an ideal approach to generate a defect-free patterned substrate for forming highly uniform and ordered quantum dot arrays with low-cost and high throughput.

Preferably, the pattern in the cured resist defined by the mold, is transferred to the semiconductor base material by the etching step mentioned previously.

In order to meet the process requirements of UV-NIL and achieve an accurate alignment of the mold relative to the patterned substrate, the mold is preferably made of transparent material. For instance, the mold may be made of one or more of the following materials: polydimethylsiloxane, fused silica, quartz.

The etching step mentioned above is preferably carried out in inductively coupled plasma and/or by reactive ion etching and/or by wet etching.

A cap layer may be deposited on top of the grown semiconductor quantum dot. Such a cap layer may protect the quantum dots during further processing.

The semiconductor quantum dot may be annealed after depositing the cap layer in order to increase the crystal quality.

For most applications, nano-holes having a circular form or cross-section will be preferred. The nano-holes may have a diameter of 30-50 nm and a depth of 20-30 nm.

For fabricating a mold, the method may further comprise the steps of first fabricating a master for the mold and fabricating the mold using the master. The master may be fabricated by electron beam lithography, focused ion beam lithography, interferometric lithography and/or block copolymer lithography (e.g. in combination with an etching process).

The semiconductor quantum dot material, the first semiconductor buffer layer and/or the second semiconductor buffer layer may consist of or may comprise one or more of the following materials: III-V compound semiconductors, II-VI compound semiconductors, III-Nitride.

Furthermore, the substrate may consist of or may comprise one or more of the following materials: silicon, III-V compound semiconductors, II-VI compound semiconductors, sapphire, SiC.

In order to precisely position the quantum dots on the substrate, it seems advantageous if a single semiconductor quantum dot is made at each nano-hole.

Another preferred embodiment relates to a method of fabricating a semiconductor quantum dot array, comprising the steps of: growing a first semiconductor buffer layer on a substrate; patterning the first semiconductor buffer layer based on photo nanoimprint lithography and an etching step using inductively coupled plasma, to form a nano-hole array in the first semiconductor buffer layer; removing surface oxide from the first semiconductor buffer layer; growing a second semiconductor buffer layer on the patterned first semiconductor buffer layer by metalorganic chemical vapor deposition; growing the semiconductor quantum dots in the nano-holes of the second buffer layer; depositing a cap layer on top of the grown semiconductor quantum dots; and annealing the semiconductor quantum dot array.

Said step of patterning the first semiconductor buffer layer may include forming circular nano-holes, wherein a single semiconductor quantum dot is subsequently made at each circular nano-hole.

### BRIEF DESCRIPTION OF THE DRAWINGS

In order that the manner in which the above-recited and other advantages of the invention are obtained will be readily understood, a more particular description of the invention briefly described above will be rendered by reference to specific embodiments thereof which are illustrated in the appended drawings. Understanding that these drawings depict only typical embodiments of the invention and are therefore not to be considered to be limiting of its scope, the invention will be described and explained with additional specificity and detail by the use of the accompanying drawings in which

FIG. 1 shows in an exemplary fashion a flow diagram illustrating steps for forming large-area, highly uniform and ordered arrays of quantum dots;

FIG. 2 shows the device's cross-sections during the process discussed with respect to FIG. 1;

FIG. 3 illustrates an embodiment of a resulting quantum dot structure in a cross-sectional view; and

FIG. 4 shows steps of patterning a substrate based on soft UV-NIL and ICP in an exemplary fashion.

### DETAILED DESCRIPTION OF THE PREFERRED EMBODIMENTS

The preferred embodiments of the present invention will be best understood by reference to the drawings, wherein identical or comparable parts are designated by the same reference signs throughout.

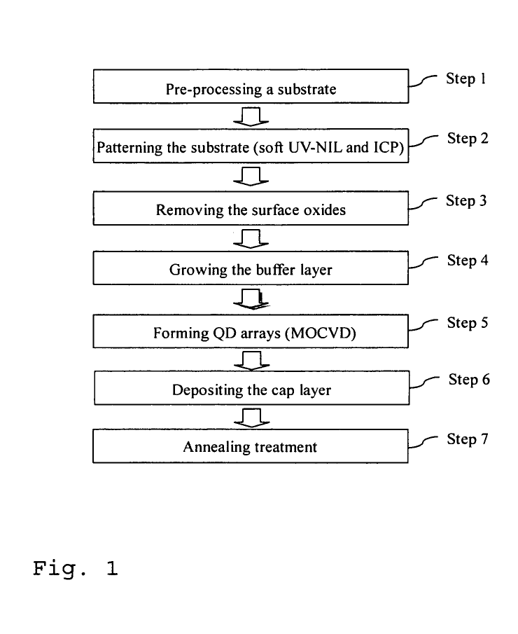

It will be readily understood that the process steps of the present invention, as generally described and illustrated in the figures herein, could vary in a wide range of different process steps. Thus, the following more detailed description of the exemplary embodiments of the present invention, as represented in FIGS. 1-4 is not intended to limit the scope of the invention, as claimed, but is merely representative of presently preferred embodiments of the invention.

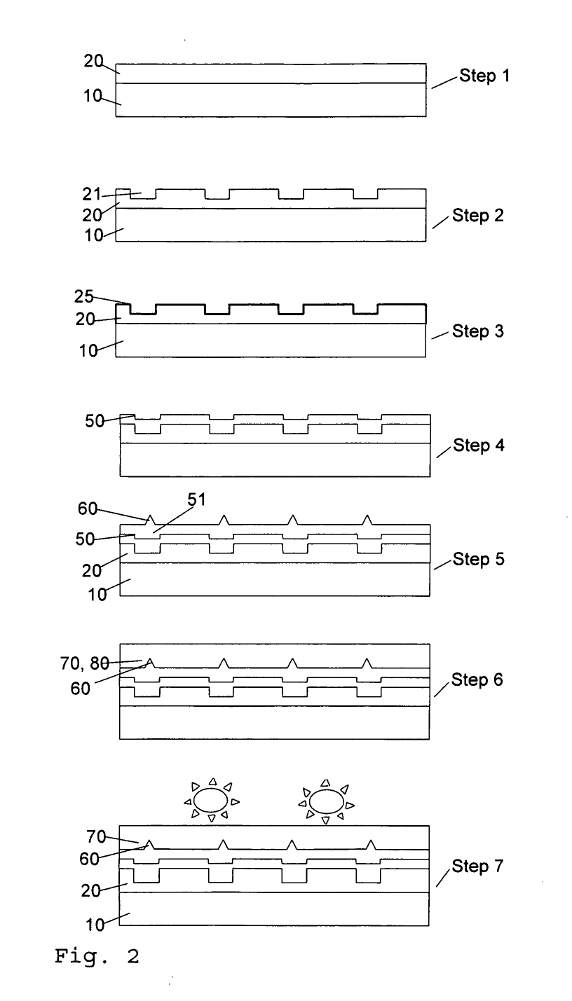

FIG. 1 shows a flow diagram comprising process steps of forming large-area, highly uniform and ordered quantum dot arrays using both soft UV-NIL (Ultra-Violet Nanoimprint Lithography) and MOCVD (Metalorganic Chemical Vapor Deposition). The corresponding cross-sectional views of the semiconductor structure during the process steps, which are indicated in FIG. 1, are depicted in FIG. 2.

In step 1, substrate pre-treatment is carried out: A GaAs substrate 10 is chemically cleaned, and then loaded into a MOCVD system. After performing a thermal process, a first buffer layer 20 is sequentially grown using MOCVD. The first buffer layer 20 is preferably made of GaAs material having a thickness of 100 nm-200 nm.

The first buffer layer 20 can largely improve the surface quality of the substrate 20 as it smoothes the substrate's surface and reduces the defects. However, the first buffer layer 20 is not mandatory. Instead, the further patterning steps may also be applied directly to the substrate's surface.

In step 2, the first buffer layer 20 is patterned. After spin-coating a thin layer of UV imprinting resist on the first buffer layer 20, a soft UV-NIL process may be utilized to replicate circular nano-hole arrays in the resist. The pattern is then transferred to the first buffer layer 20 by an ICP (Inductively Coupled Plasma) etching process. The etching process yields a patterned first buffer layer 20 having nanopore arrays including nano-holes 21 with a diameter of ca. 30-50 nm and a depth of ca. 20-30 nm. The patterned first buffer layer 20 may be used to act as a template to form quantum dots with a high level of uniformity at predefined positions (see FIG. 2).

In order to make a mold for the soft UV-NIL process, a master may be first fabricated using EBL (Electron-Beam Lithography) and RIE (Reactive Ion Etching), followed by a vacuum casting process to replicate a PDMS (Polydimethylsiloxane) mold.

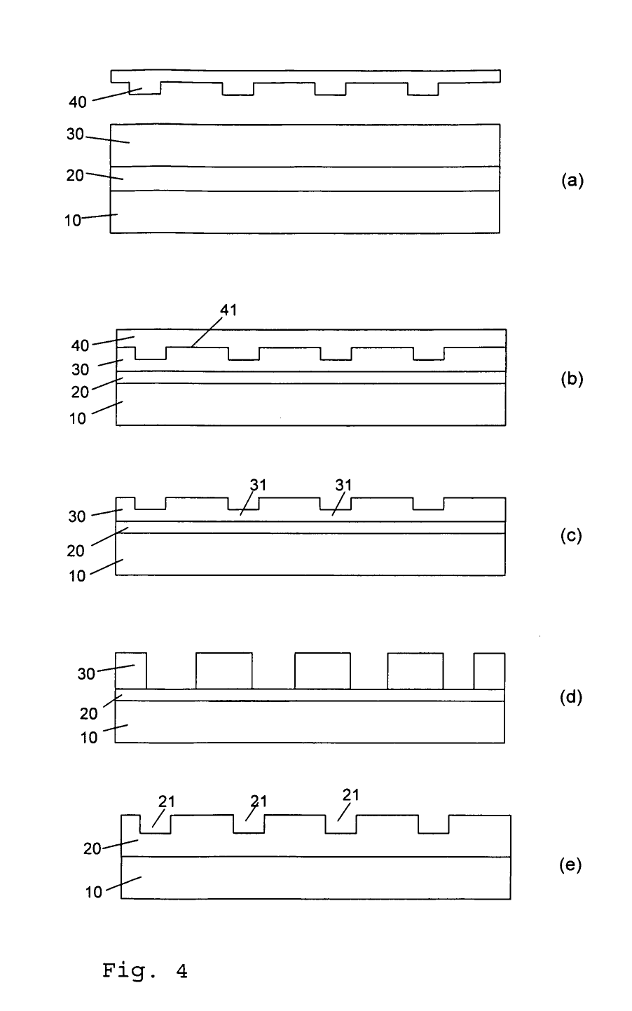

A more detailed diagram showing the patterning of the first buffer layer 20 through the combination of soft UV-NIL and ICP (Inductively Coupled Plasma) is presented in FIG. 4.

As shown in section (a) of FIG. 4, a thin layer of imprint resist 30 (UV-curable liquid photopolymer) is spin-coated onto the first buffer layer 20. Then a PDMS mold 40 is brought into contact with the first buffer layer 20 and they are pressed together under certain pressure, as shown in section (b) of FIG. 4.

After the cavities (trenches) 41 of the mold 40 are fully filled by the resist 30, the resist is cured in UV light and becomes solid. The mold 40 is then separated from the first buffer layer 20 and the patterned resist 30 is left on the first buffer layer 20 as shown in section (c) of FIG. 4.

In section (d) of FIG. 4, the residual layer 31 of the resist 30 is removed by reactive ion etching. Furthermore, a subsequent pattern transfer process through an ICP process is used to transfer the pattern in the resist 30 to the first buffer layer 20. As a result, a patterned first buffer layer 20 with nanopore arrays is generated. The nanopores 21 may have a diameter between 10 and 100 nm (e.g. 40 nm) and a depth between 10 nm and 100 nm (e.g. 30 nm).

For use in step 2, a PDMS mold 40 may be fabricated by the following processes: An ITO (Indium Tin Oxide) film layer as thin as 10-20 nm is firstly deposited on a quartz substrate, preferably by PECVD (Plasma Enhanced Chemical Vapor Deposition). SiO₂ may then be deposited on the ITO. This oxide may be coated with an e-beam resist, which is patterned by EBL and subsequently used as an etch mask for the oxide pattern transfer. After etching the SiO₂ and the strip resist, a master with a nanopore array having nanopores of 10-100 nm (e.g. 40 nm) diameter, is obtained. Based on the master, a vacuum casting process may be used to replicate a mold. These steps yield a transparent soft PDMS mold with nanopillar arrays of 10-100 nm (e.g. 40 nm) diameter as shown in FIG. 4, section (a) (reference numeral 40).

In step 3, the surface oxide 25 on the first buffer layer 20 is removed, preferentially by using a hydrogen-assisted cleaning process. Such a cleaning process avoids damaging the pattern. For instance, the first buffer layer 20 may first be chemical cleaned and loaded into a MOCVD chamber. Then the patterned first buffer layer 20 may be exposed to hydrogen to remove residual remains of resist and the native oxide 25. The surface oxide can be removed by exposure to a hydrogen and AsH₃ environment at ca. 720° C. for 5-7 minutes.

During step 4, a second buffer layer 50 consisting of GaAs-material is grown on the first buffer layer 20 by MOCVD. The second buffer layer 50 improves the surface quality of the first buffer layer 20 and may also reduce the size of the nano-holes 21 in the first buffer layer 20. The thickness of the second buffer layer 50 preferably ranges between 10-30 nm. The MOCVD may be carried out at a temperature of 680° C. and a growth rate of 0.3 mL/s (ML: monolayers).

In step 5, InAs quantum dot arrays are formed by InAs deposition: After growing the second buffer layer 50, the temperature is ramped down to ca. 500° C., to subsequently grow InAs quantum dots 60. An InAs amount of ca. 2 mL is deposited. After the deposition of the InAs quantum dot layer, a 70 second growth interruption is inserted to enhance the formation of the quantum dots 60. The following process parameters may be used to grow the InAs quantum dots 60: growth temperature Ts: 480° C.-500° C.; InAs deposition amount: ca. 2 monolayers; V/III ratio: 2-5 (Tertiarybutylarsine or AsH₃).

InAs preferentially nucleates in the nano-holes 51 of the second buffer layer 50, therefore the amount of InAs deposited is preferably adjusted to the density of the pattern in order to avoid InAs quantum dot formation outside the patterned areas (i.e. the nano-holes 51).

In order to achieve uniform regular quantum dot arrays with a single quantum dot 60 at each nano-hole 51 (nucleation site) the process preferably includes a deposition at a relatively low temperature and subsequent annealing treatment. A matching of nano-hole size and a growth condition is important to achieve a regular quantum dot array.

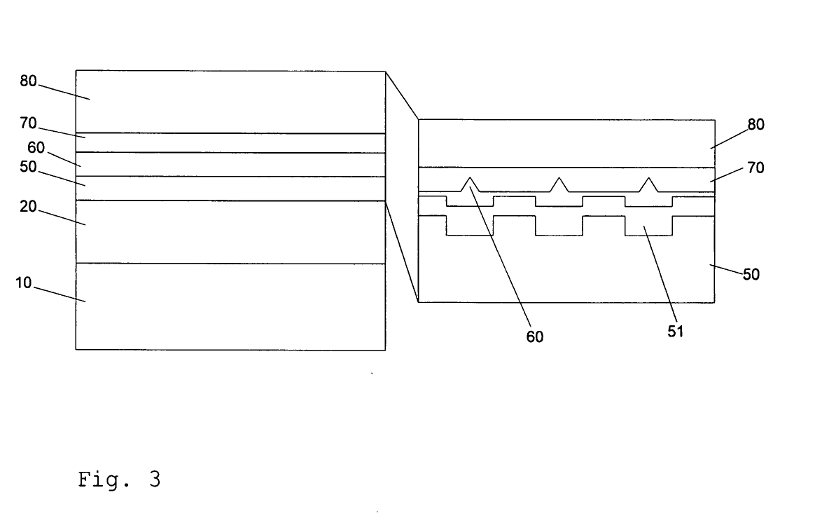

In step 6,the quantum dots 60 are capped with a first cap layer 70 (see FIG. 3). The first cap layer 70 comprises GaAs-material and has a thickness of ca. 3 nm. The GaAs-material is preferably grown at a growth rate of ca. 0.3 mL/s. The other growth parameters may be the same as those used for the growth of the InAs quantum dots 60 in step 5. The growth is then finished by growing a second GaAs cap layer 80 at 600° C. and a growth rate of 1 μm/h whereas the other parameters remain unchanged. The thickness of the sec- and cap layer 80 is preferably about 70 nm.

In step 7, an annealing treatment is carried out. The annealing treatment may be performed at ca. 600° C. for about one hour.

As pointed out above, the second buffer layer 50 is useful for improving the surface quality of the first buffer layer 20. However, the second buffer layer 50 is not mandatory. Alternatively, the quantum dots may be grown on the surface of the first buffer layer 20 or on the surface of the substrate 10.

FIG. 3 illustrates a closer view of the resulting structure after completing step 7. The patterned first and second buffer layers 20 and 50 are indicated as well as the first and second cap layers 70 and 80. In the embodiment shown in FIG. 3, the layers may have the following thicknesses:

| | |
|---|---|
| First buffer layer 20 | 100 nm |
| Second buffer layer 50 | 20 nm |
| First cap layer 70 | 3 nm |
| Second cap layer 80 | 70 nm |

As apparent from the above, the embodiments explained above provide a method of forming large-area, site-controlled, highly uniform and ordered arrays of quantum dots with low-cost and high throughput. The embodiments incorporate soft UV-NIL and MOCVD, and may comprise the steps of: patterning a substrate with circular nano-hole arrays using the combination of soft UV-NIL and ICP, followed by growing the quantum dot arrays using the MOCVD process. The nucleation centers of quantum dots are defined by the nano-holes of the patterned substrate. By changing the position and size of the nano-hole arrays, and together with the optimized growth processes and conditions, the site, quantum dot shape and size, as well as uniformity and ordering of the quantum dot arrays can be accurately controlled. The embodiments incorporate the advantages of both the soft UV-NIL and the MOCVD. Namely, soft UV-NIL has the ability to pattern the substrate with large-area nano-hole arrays at low cost and high throughput. The MOCVD process has a higher productivity to growth of quantum dots compared to other epitaxial growth processes. In addition, to realize regular quantum dot arrays and ensure a single quantum dot at each nano-hole, a low temperature deposition and subsequent annealing treatment as well as smooth bottom surface for these nanopores may be adopted. Therefore, the combination of soft UV-NIL with selective MOCVD growth process can result in a higher degree of control over quantum dot shape and size, size uniformity, nucleation site, which can form large-area, site-controlled, highly uniform and ordered arrays of quantum dots with low-cost and high throughput. In particular, the presented embodiments have the prominent ability to produce quantum dot arrays in mass production, and to fabricate either the high dense quantum dot arrays or low dense quantum dot arrays for achieving single quantum dots.

In summary, compared to prior art methods, the embodiments described above have the following prominent advantages:

(1) The embodiments have the ability to form large area, site-controlled, highly uniform and ordered arrays of quantum dots with low cost and high throughput by incorporating the advantages from both UV-NIL and MOCVD.
(2) The embodiments provide the ability to produce quantum dot arrays in mass production, and to fabricate either high dense quantum dot arrays or quantum dot arrays with a low density for achieving single quantum dots. Mass production techniques of fabricating quantum dot arrays has a high potential as an enabling technology to improve the performances of quantum dot-based products and breaks through the technical bottlenecks which can restrict the commercial quantum dot-based products.
(3) The embodiments offer a perfect solution for solving the inherent problems of the non-uniformity and random ordering resulting from prior art self-assembly processes of growing quantum dots. The embodiments allow accurately controlling the quantum dot size and position as well as improving uniformity. Highly uniform and ordered long-range quantum dot arrays may have various potential applications such as single photon emitters and high integration of single quantum dot devices, quantum dot memories, highly efficient quantum dot lasers, and the third generation solar cells of enhanced conversion efficiency, etc.

The embodiments discussed above with respect to FIGS. 1-4, use soft UV-NIL for patterning the substrate or buffer layers grown thereon. However, other technologies including electron-beam lithography (EBL), X-ray lithography, focused ion-beam lithography (FIB), interferometric optical lithography, AFM, STM, AAO (anodic aluminum oxide), nanosphere lithography, block copolymer lithography, may be used to pattern the substrate or the buffer layers.

In conclusion, the embodiments described above may deal with:
1. A three-dimensional structure: 0-dimensional quantum dots may be incorporated in an epitaxial 3-dimensional device structure, e.g.: a single photon source with 1 dot in a vertical emitter (similar to a VCSEL structure), or a memory device or a laser device with many dots embedded in a single common semiconductor matrix.
2. Positioning of semiconductor dots on the wafer: The semiconductor dots may nucleate at holes defined by the lithography process.
3. Growth of 0-dimensional dots applying the Stranski-Krastanow mechanism: The critical thickness for the 2-dimensional->3-dimensional growth transition is locally exceeded at the position of the holes.
4. Quantum dots in a 3-dimensional structure: The quantum dots are formed by the self-organized Stranski-Krastanow transition and epitaxy of a capping semiconductor matrix material. All barriers around the dot are given by the epitaxial semiconductor matrix material.
5. 3-dimensional device structures: The structures may contain just 1 dot, or a high density dot layer, or vertical stacked layers of dots. The first dot layer may be formed as stated in point 2, subsequently deposited dot layers in a stack may be formed by strain coupling. Strain coupling is a feature specific for 3-dimensional epitaxial matrix structures and can not appear in 1-dimensional structures.
6. A quantum dot LED which is a 3-dimensional device containing a single dot, or a high-density dot layer, or a vertical dot layer stack.
7. Three-dimensional structures containing 0-dimensional structures, with nearest neighbour distances down to some 10 nm.

### REFERENCE NUMERALS

10 substrate
20 first buffer layer
21 nanopore/nano-hole
25 surface oxide
30 resist
31 residual layer
40 mold
41 trench
50 second buffer layer
51 nano-hole
60 quantum dot
70 first cap layer
80 second cap layer

1. A method of fabricating at least one semiconductor quantum dot at a predefined position, comprising the steps of:
patterning a semiconductor base material using nanoimprint lithography and an etching step, to form at least one nano-hole at the predefined position in the semiconductor base material; and
growing the at least one semiconductor quantum dot in or on top of the at least one nano-hole by metalorganic chemical vapor deposition.

2. The method of claim 1, further comprising the steps of:
growing a first semiconductor buffer layer on a substrate said first semiconductor buffer layer forming said semiconductor base material; and
patterning the first semiconductor buffer layer based on said nanoimprint lithography and said etching step, to form said nano-hole in the first semiconductor buffer layer.

3. The method of claim 1 wherein said nanoimprint lithography is a photo nanoimprint lithography comprising the steps of:
applying a photo curable liquid resist to the semiconductor base material;
pressing a mold and the semiconductor base material together;
curing the photo curable liquid resist; and
separating the mold from the cured photo curable liquid resist.

4. The method of claim 3,
wherein said photo curable liquid resist is an UV-light curable liquid resist; and
wherein curing the UV-light curable liquid resist comprises applying UV-light to the UV-light curable liquid resist.

5. The method of claim 4 wherein said mold is made of transparent material.

6. The method of claim 1 wherein said etching step is carried out in inductively coupled plasma and/or by reactive ion etching and/or by wet etching.

7. The method of claim 1 wherein a cap layer is deposited on top of the grown semiconductor quantum dot.

8. The method of claim 7 wherein the semiconductor quantum dot is annealed after depositing the cap layer.

9. The method of claim 1 wherein said nano-hole is a circular nano-hole.

10. The method of claim 9 wherein said nano-hole in the semiconductor base material has a diameter of 30-50 nm and a depth of 20-30 nm.

11. The method of claim 5 wherein
a master for the mold is fabricated and the mold is fabricated using the master, and
the master is fabricated by electron beam lithography, focused ion beam lithography, interferometric lithography and/or block copolymer lithography.

12. The method of claim 1 wherein the semiconductor quantum dot material, a first semiconductor buffer layer and/or a second semiconductor buffer layer consist of or comprise one or more of the following materials: compound semiconductors, II-VI compound semiconductors, III-Nitride.

13. The method of claim 1 wherein a substrate consists of or comprises one or more of the following materials: silicon, III-V compound semiconductors, II-VI compound semiconductors, sapphire, SiC.

14. The method of claim 1 wherein a single semiconductor quantum dot is made at each nano-hole.

15. A method of fabricating a semiconductor quantum dot array, comprising the steps of:
growing a first semiconductor buffer layer on a substrate;
patterning the first semiconductor buffer layer based on photo nanoimprint lithography and an etching step using inductively coupled plasma, to form a nano-hole array in the first semiconductor buffer layer;
removing surface oxide from the first semiconductor buffer layer;
growing a second semiconductor buffer layer on the patterned first semiconductor buffer layer;
growing the semiconductor quantum dots in the nano-holes of the second buffer layer by metalorganic chemical vapor deposition;
depositing a cap layer on top of the grown semiconductor quantum dots; and
annealing the semiconductor quantum dot array.

16. The method of claim 15,
wherein patterning the first semiconductor buffer layer includes forming circular nano-holes; and
wherein a single semiconductor quantum dot is made at each circular nano-hole.

17. The method of claim 16 wherein said nanoimprint lithography is a photo nanoimprint lithography comprising the steps of:
applying a photo curable liquid resist to the first semiconductor buffer layer;
pressing a mold and the first semiconductor buffer layer together;
curing the photo curable liquid resist; and
separating the mold from the cured photo curable liquid resist.

18. The method of claim 17 wherein a master for the mold is fabricated and the mold is fabricated using said master.
